(19) United States
(12) Patent Application Publication
(10) Pub. No.: US 2006/0234486 A1
(43) Pub. Date: Oct. 19, 2006

(54) Wafer separation technique for the fabrication of free-standing (Al,In,Ga)N wafers

(76) Inventors: James S. Speck, Goleta, CA (US); Troy J. Baker, Santa Barbara, CA (US); Benjamin A. Haskell, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(21) Appl. No.: 11/403,624

(22) Filed: Apr. 13, 2006

Related U.S. Application Data
(60) Provisional application No. 60/670,810, filed on Apr. 13, 2005.

(51) Int. Cl. H01L 21/3205; H01L 21/28; H01L 21/44; H01L 21/4763

(52) U.S. Cl. 438/590; 438/602; 438/572

(57) ABSTRACT

A method of fabricating free-standing (Al, In, Ga)N substrates, by in situ separation of thick epitaxially grown nitride films from their foreign substrates. A suitable substrate for (Al, In, Ga)N film growth is selected, and foreign ions are implanted in the substrate to form a comparatively sharp concentration profile. An (Al, In Ga)N film is deposited on the substrate, and the deposited film is cooled to introduce thermal expansion mismatch-related strain, so that the film spontaneously separates from the substrate.

### CROSS-REFERENCE TO RELATED APPLICATIONS

This application claims the benefit under 35 U.S.C. Section 119(e) of the following co-pending and commonly-assigned U.S. patent application:

United States Provisional Patent Application Ser. No. 60/670,810, filed on Apr. 13, 2005, by James S. Speck, Troy J. Baker, and Benjamin A. Haskell, entitled “WAFER SEPARATION TECHNIQUE FOR THE FABRICATION OF FREE-STANDING (Al, In, Ga)N WAFERS,” attorneys' docket no. 30794.131-US-P1;

which application is incorporated by reference herein.

This application is related to the following co-pending and commonly-assigned applications:

U.S. Utility Patent Application Ser. No. ______, filed on same date herewith, by James S. Speck, Benjamin A. Haskell, P. Morgan Pattison and Troy J. Baker, entitled “ETCHING TECHNIQUE FOR THE FABRICATION OF THIN (Al, In, Ga)N LAYERS,” attorneys' docket no. 30794.132-US-Ul (2005-482-2), which application claims the benefit under 35 U.S.C. Section 119(e) of U.S. Provisional Patent Application Ser. No. 60/670,790, filed on Apr. 13, 2005, by James S. Speck, Benjamin A. Haskell, P. Morgan Pattison and Troy J. Baker, entitled “ETCHING TECHNIQUE FOR THE FABRICATION OF THIN (Al, In, Ga)N LAYERS,” attorneys docket number 30794.132-US-P1 (2005-509);

which applications are incorporated by reference herein.

### BACKGROUND OF THE INVENTION

1. Field of the Invention

The present invention relates to a wafer separation technique for the fabrication of free-standing (Al, In, Ga)N wafers.

2. Description of the Related Art

A variety of chemical, thermodynamic, and engineering issues have largely prevented researchers from fabricating large crystals of gallium nitride (GaN), necessitating the use of heteroepitaxial crystal growth techniques to form GaN substrates. The most common GaN substrate synthesis technique is hydride vapor phase epitaxy (HVPE), in which GaN films may be grown at tens to hundreds of micrometers per hour on foreign substrates, including sapphire (Al₂O₃), silicon carbide (SiC), silicon (Si), spinel (MgAl₂O₄), lithium aluminate (LiAlO₂), and gallium arsenide (GaAs). Each of these substrates is mismatched to the GaN films in terms of the crystals' lattice parameters, thermal expansion coefficients, and other thermal, electrical, and optical parameters. The lattice and thermal expansion mismatch frequently cause the formation of linear, planar, and bulk defects both during growth and upon cooling from the growth temperature. The HVPE-grown nitride films may range from a few micrometers to tens of millimeters thick, allowing growth of thin membranes that must be supported by foreign carriers, ˜300 μm thick films that can provide single free standing wafers, or pseudo-boules that may be sliced to yield self-supporting wafers. It is generally desirable to remove the substrate from thick GaN films, yielding free-standing GaN substrates that may be subsequently used for device fabrication by other growth techniques, including metalorganic chemical vapor deposition (MOCVD) and molecular beam epitaxy (MBE).

The most commonly grown (Al, In, Ga)N material for fabrication of free-standing nitride substrates is presently GaN. Several approaches have been developed for the removal of GaN films from their substrates. Chemical etching may be used to remove GaAs and Si substrates. However, GaN films grown on GaAs and Si tend to exhibit inferior quality to those grown on more robust substrates such as Al₂O₃ and SiC. Sapphire is presently the preferred substrate material for most GaN crystal growth, but its chemical stability and robustness make it difficult to remove.

Laser-assisted debonding is commonly used to remove wide band gap substrates like Al₂O₃ and MgAl₂O₄. In this process, a high-intensity pulsed excimer laser the back side of a substrate/nitride film composite to vaporize the GaN at the substrate/film interface. This process has several limitations. First, the optical band gap of the substrate must be substantially larger than that of the nitride film to be removed; thus GaN films cannot be removed from SiC substrates by laser debonding. Second, the laser pulses generate shockwaves at the film/substrate interface that can be forceful enough to fracture the substrate or nitride film (or both) in an undesirable manner. Third, the lasers required for laser debonding are large, expensive, and require significant energy inputs to operate. The cost and complexity of laser debonding systems further increases if one wishes to debond AlGaN or AlN films from foreign substrates.

Another approach to substrate removal is dry etching via ion bombardment techniques, as is done commercially to remove SiC substrates from AlN films. However, this approach is slow, costly, and can cause damage to the remaining GaN layers.

Another class of wafer separation techniques relies on the deposition of mask layers prior to growth that encourage separation of thick GaN films from the substrate at the weak mask interface. Hitachi Cable, Ltd., recently reported on a technique it termed “void-assisted separation” (VAS), in which thick HVPE-grown GaN films separate from sapphire substrates on cooling through the use of porous titanium nitride (TiN) masks formed on MOCVD-grown GaN templates on sapphire substrates. While this technique provides advantages in the film separation stage of processing, it is cumbersome in that no fewer than three growth systems are required for the process, extending processing times and introducing several potential sources of variability, including impurities at the growth surface, into the process. This process further requires that the nitride film thickness be in excess of approximately 50 μm, making it entirely unsuitable for the fabrication of thin III:N membrane structures. Therefore, a clear need exists in the field for a comparatively simple and cost-effective, wafer separation technique that may be used to remove both thin and thick (Al, In, Ga)N films from their substrates.

A relevant wafer separation technique was developed for use in the silicon semiconductor industry by the Laboratoire d' Electronique de Technologie de l' Information within the French Atomic Energy Commission (CEA-LETI). This process, licensed to and trademarked by SOITec, is referred to as Smart Cut₁₉₈. The process involves implanting foreign ions, particularly hydrogen or noble gas ions, into a substrate to form a sharp subsurface ion concentration profile. The substrate is then bonded or fused to a “handle” wafer. The composite system is thermally annealed at 300-700° C., allowing the implanted ions to migrate laterally to form microvoids within the substrate. Upon cooling from the annealing temperature, stresses associated with the microvoids cause the original substrate layer to spontaneously cleave along a plane parallel to the substrate surface. The thin film of the original substrate that was above the implanted layer remains fused to the handle wafer and is used for subsequent device fabrication, while the remains of the original substrate may be reused in the process by subsequent implanting and bonding to another handle wafer.

The primary application for Smart Cut₁₉₈ is for the manufacture of Silicon-On-Insulator (SOI) substrates. First, a silicon wafer is oxidized. Then, ions, typically hydrogen (H⁺), are implanted through the oxide. The doses of H⁺ ions range from 3×10¹⁶ cm⁻² to 1×10¹⁷ cm⁻². The oxide layer is then bonded to another substrate. Finally, annealing at temperatures between 400 and 600° C. causes the microvoid formation and cleavage of the substrate. The result is a bonded wafer with a layer of SiO₂ and a thin layer of exposed Si, which can range from 20 nm to several microns.

The process of Smart Cut^{™}has been applied to SiC, GaAs, indium phosphide (InP), diamond, germanium (Ge), LiAlO₂, and Al₂O₃. The dose for each type of ion implanted is reported to be independent of the substrate being implanted. More recently, both SOITec and a competitor, US-based Silicon Genesis, have reported on using Smart Cut-like technology to form thin GaN films that are bonded to carrier wafers for use as pseudo-GaN substrates. The process described in the patent literature is cumbersome, requiring the growth of a GaN film, ion implantation of the GaN film, wafer bonding, annealing to separate the GaN film from its original substrate, polishing, and then growth of a GaN device structure or substrate upon the thin GaN membrane bonded to the handle wafer. To the best of the authors' knowledge, this process has not been successfully commercialized at this time. This lack of development may be because carrying out this process using a standard c-plane GaN template layer would yield a debonded film having a nitrogen-face c-plane as its free surface. As growth of N-face c-plane GaN is typically far inferior in quality to Ga-face c-plane GaN, this separation method is unsuitable for the fabrication of useful pseudo-free-standing GaN layers for device regrowth.

The present invention improves upon existing wafer separation technology and provides a comparatively simple, reliable, and cost-effective means of removing (Al, In, Ga)N films from their substrates. Ion implantation technology has been extensively developed in the silicon microelectronics industry and is therefore readily available at low costs. The invention differs substantially from Smart Cut^{™}technology in that it eliminates the need for handle wafers, wafer bonding, and post-separation growth steps to form monolithic nitride substrates. The invention improves yields compared to conventional laser-liftoff techniques and is compatible with any conceivable substrate, independent of the chemical or mechanical properties of the substrate.

### SUMMARY OF THE INVENTION

The present invention provides a method of fabricating free-standing (Al, In, Ga)N substrates. Such GaN substrates have widespread application in high-power electronic and optoelectronic devices. However, because of the difficulties in and cost of fabricating bulk GaN crystals, free-standing GaN substrates are underused in GaN-based device applications.

A further object of this invention is to minimize the deleterious effects of stress induced by thermal expansion coefficient mismatch in nitride heteroepitaxy. Thermal expansion coefficient mismatch between a (Al, In, Ga)N film and its foreign substrate frequently causes cracking of the nitride film and/or the substrate upon cooling from the film growth temperature. This invention eliminates undesirable cracking of the film and substrate by encouraging cleavage of the composite system along a plane parallel to the growth plane.

An additional object of the present invention is to minimize pre- and post-growth processing of the substrate and epitaxial grown (Al, In, Ga)N wafer required to form epi-ready, free-standing (Al, In, Ga)N substrates. This invention offers a simple means of producing (Al, In, Ga)N substrates using simple and inexpensive ion implantation and hydride vapor phase epitaxy with minimal post-growth processing.

Another object of this invention is to provide a means for the reuse of potentially expensive foreign substrates following growth of thick nitride films. This object is particularly significant for the recycling of expensive nonpolar silicon carbide substrates.

### BRIEF DESCRIPTION OF THE DRAWING

Referring now to the drawing in which like reference numbers represent corresponding parts throughout:

FIG. 1 is a flowchart that illustrates the process steps of the preferred embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

Bulk GaN crystals of sufficient size to cut into substrate wafers have not been produced by non-epitaxial growth methods, necessitating the use of heteroepitaxial crystal growth techniques to produce (Al, In, Ga)N films. Once thick (>300 μm) films are grown, the foreign substrates should be removed prior to subsequent use as large-area free-standing substrates. The present invention describes a novel method to allow in situ separation of thick epitaxially-grown nitride films from their foreign substrates. A substrate or template is implanted with a dose of hydrogen, helium, or other noble gas ions, forming a sharp subsurface ion concentration profile. The substrate/template is loaded into a HVPE growth system. Upon heating to the growth temperature and throughout the growth of a thick nitride film on the wafer, the implanted ions migrate and coalesce, forming voids in the substrate/template. Upon cooling from the growth temperature following the nitride film growth, the voids thus formed cause the substrate/template to spontaneously fracture along a plane parallel to the wafer surface. The thin remaining fragment of the substrate/template may be easily removed by polishing or a variety of dry etching techniques. This process will greatly simplify the fabrication of thick, free standing III:N substrates by HVPE growth.

Technical Description

The present invention improves upon existing wafer separation technology and provides a comparatively simple, reliable, and cost-effective means of removing (Al, In, Ga)N films from their substrates. This invention is based on Smart Cut^{™}technology, but eliminates the need for handle wafers, wafer bonding, and distinct annealing furnaces, all of which are integral parts of the Smart Cut^{™}process. Before epitaxial growth, suitable substrate or template wafers are implanted with a dose and profile of foreign ions so as to form subsurface damage layers. The ions, dose, and profile are selected to encourage microvoiding during a subsequent nitride film growth process. Upon cooling from the film growth temperature, thermal expansion coefficient mismatch between the substrate and film generates large stresses in the composite system. The microvoids formed due to ion implantation act as stress concentrators, causing the substrate/template to spontaneously fracture parallel to the growth surface. This process yields a cleaved substrate that may be re-polished for subsequent use, and a free standing (Al, In, Ga)N wafer with a thin membrane of the substrate/template still attached. The remaining substrate film fragment may be left in place or easily removed by a variety of polishing or etching techniques.

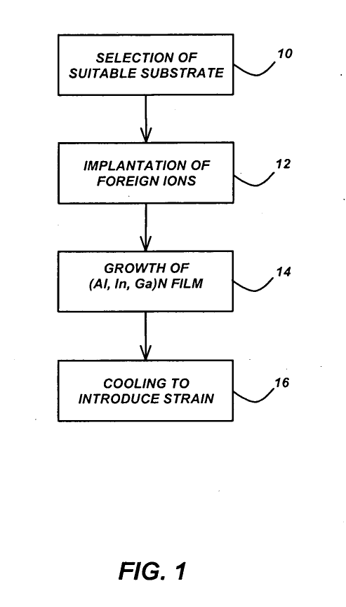

FIG. 1 is a flowchart that illustrates the process steps of the preferred embodiment of the present invention. Specifically, these steps represent a method of in situ separation of epitaxially-grown nitride films from their foreign substrates. Those skilled in the art will recognize that the present invention is not limited to these precise steps.

Block 10 represents selecting a suitable substrate for (Al, In, Ga)N film growth. Such substrates include, but are not limited to, (Al, In, Ga)N, sapphire (Al₂O₃), silicon carbide (SiC), silicon (Si), spinel (MgAl₂O₄), or lithium aluminate (LiAlO₂).

Block 12 represents implanting foreign ions in the substrate to form a comparatively sharp concentration profile of foreign ions below a surface of the substrate. The foreign ions may include, but are not limited to, hydrogen, helium, argon, or other noble gas ions. The implanted foreign ions migrate and coalesce, forming voids in the substrate, wherein the voids cause the substrate to spontaneously fracture along a separation plane parallel to the substrate surface upon cooling. Note that the substrate may be implanted with foreign ions prior to placing the substrate in a growth or deposition chamber, thus providing a substrate having a concentration profile of foreign ions below a surface of the substrate. In this way, all subsequent steps (blocks 14-16) may be carried out in-situ within the growth or deposition chamber.

Block 14 represents depositing or growing a film such as an (Al, In, Ga)N film on the surface of the substrate. Preferably, the film has a thickness of at least 50 microns. The growth can be performed by a variety of techniques, including, but not limited to, sputtering, metal-organic halide vapor phase epitaxy, or hydride vapor phase epitaxy. The examples in this disclosure will focus principally on hydride vapor phase epitaxy. Moreover, this growing step generally will also include heating the substrate. If properly executed, the surface of the substrate on which the film is deposited will be smoother than the cleaved surface along the concentration profile and therefore superior for growth.

Block 16 represents cooling the film and substrate to introduce thermal expansion mismatch-related strain, wherein the film separates from the substrate spontaneously. Specifically, the grown film will separate from the bulk of the substrate spontaneously and along the concentration profile to form a free standing wafer. The film is a free-standing wafer, positioned on top of a membrane that is a fragment of the original implanted substrate, because it is self-supporting and rigid. The advantage of this method is that it allows for stress management in the cooling process. One of the biggest problems with GaN growth on foreign substrates is the stress that develops on cooling due to thermal expansion mismatch between the GaN and the foreign substrate. This invention eliminates the bulk of the foreign substrate and much of this stress with it.

The remaining fragment of the substrate may be removed from the grown film by polishing or dry etching. The free-standing wafer minimizes contamination with unwanted impurities, and also minimizes pre-growth and post-growth processing. The post-growth processing is reduced by the elimination of planarization to manage curvature of the wafer, reduction of polishing requirements, and reduced cracking. As noted above, the concentration profile is at a specified depth below the substrate surface (preferably the depth is less than 1 micron), the membrane has a thickness given by the specified depth, and the separation is along at least one plane of the substrate. One of the advantages of the method is that it minimizes the number of steps required to fabricate a free standing wafer. For example, the method does not require a pre-treatment layer before depositing the film on the substrate.

The end result of these steps is a free standing III:N substrate or wafer fabricated using the recited method. Moreover, an electronic or optoelectronic device may be co-grown with the film fabricated using this method.

### EXAMPLES

The following examples further describe these process steps and their results.

### Example 1

An m-plane 6H-SiC substrate is implanted with a dose of He⁺ ions with a peak concentration of 5×10¹⁶ cm⁻² at a depth of 900 nm from the surface. The substrate is then loaded into a HVPE reactor, in which a 300 μm thick m-plane Al_{0.5}Ga_{0.5}N film is grown at 1200° C. During the course of the growth, the He⁺ ions migrate laterally and coalesce to form microvoids approximately on a plane parallel to the SiC m-plane. Upon cooling, stress due to thermal expansion mismatch causes the m-plane SiC substrate to spontaneously cleave at the microvoided layer. The remaining SiC substrate is re-polished and used for a subsequent growth. The m-plane AlGaN film now exists as a free-standing wafer with an approximately 900 nm thick SiC membrane attached to its back side. This SiC membrane is allowed to remain in place as it will not affect subsequent growth on the AlGaN growth surface.

### Example 2

A c-plane Al₂O₃ substrate is implanted with a dose of H⁺ ions with a peak concentration of 3×10¹⁶ cm⁻² at a depth of 1000 nm from the surface. The substrate is then loaded into a HVPE reactor, in which a 300 μm thick Si-doped c-plane GaN film is grown at 1050° C. During the course of the growth, the H⁺ ions migrate laterally and coalesce to form microvoids approximately on a plane parallel to the Al₂O₃ c-plane. Upon cooling, thermal expansion mismatch related strain causes the c-plane Al₂O₃ substrate to spontaneously cleave at the microvoided layer. The c-plane GaN film now exists as a free-standing wafer with an approximately 1000 nm thick Al₂O₃ membrane attached to its back side. The Al₂O₃ membrane is removed by brief chemi-mechanical polishing to facilitate backside electrical contacting of subsequently grown devices on the free-standing GaN substrate.

### Example 3

An r-plane Al₂O₃ substrate is implanted with a dose of Ar⁺ ions with a peak concentration of 1×10¹⁷ cm⁻² at a depth of 500 nm from the surface. The substrate is then loaded into a HVPE reactor, in which a 200 μm thick Si-doped a-plane GaN film is grown at 1050° C. Following the growth of this thick GaN film, a 5 μm-thick pn-junction diode structure is grown by adding Si and Mg to subsequent layers. During the course of the growth, the Ar⁺ ions migrate laterally and coalesce to form microvoids approximately on a plane parallel to the Al₂O₃ r-plane. Upon cooling, thermal expansion mismatch related strain causes the r-plane Al₂O₃ substrate to spontaneously cleave at the microvoided layer. The a-plane GaN film and diode now exist as a free-standing wafer with an approximately 500 nm thick Al₂O₃ membrane attached to the back side of the nitride film. The Al₂O₃ removed by brief chemi-mechanical polishing to facilitate backside contacting to the n-type region of the pn-junction diode structure. Thus an optoelectronic device structure is readily formed by the present invention.

Possible Modifications and Variations

The preferred embodiment described above offers a general description of the present invention. The examples cited are for illustrative purposes only and do not limit the scope of the invention. The ion composition, dose, and depth profiles described are representative of feasible implementations of the invention. Indeed, virtually any type of ion is compatible with this invention in addition to the hydrogen and noble gas ions recommended above. Ion doses ranging from approximately 1×10¹⁴ to over 1×10¹⁹ cm⁻² may prove useful in the practice of this invention. The precise shape of the ion concentration profile does not significantly affect the microvoiding process provided that a sufficient ion concentration is achieved to facilitate microvoiding below the substrate surface.

Several monolithic substrates have been described in the preferred embodiment above. Additional substrates, and indeed several polymorphs and/or orientations of the substrates listed can be used in the practice of this invention. The “substrate” may comprise a substrate structure such as a multilayered structure, monolithic crystal, buffer or a template. For example, a 1 μm thick GaN film could be grown on a 200 nm thick AlN buffer layer on an m-plane 4H-SiC substrate by MBE or MOCVD. H⁺ ions could then be implanted to a depth of 500 nm into the GaN film, or alternatively through the GaN and AlN layers into the SiC substrate. Such buffer or template layers may be, but need not be, deposited by the same growth technique as is used for the nitride film deposition. For example, a ZnO buffer could be sputtered on a c-plane Al₂O₃ substrate, with H⁺ ions implanted through the ZnO buffer into the sapphire substrate. Alternatively, the template may be a reduced defect-density nitride substrate prepared by one of many defect reduction techniques, including lateral overgrowth (ELOG) techniques. The template may include foreign masks, inhomogeneously distributed defects, etc. While adding to the complexity of the process, the use of such multilayered structures is entirely within the scope of the present invention. The only relevant requirements for the substrate/template are that the substrate material be such that a desirable form of (Al, In, Ga)N will grow on it and that the substrate be sufficiently chemically, thermally, and mechanically compatible with the growth environment to be used for nitride film deposition.

The preferred embodiment and examples described above included the growth of thick AlₓIn_{y}Ga_{z}N (0≦x≦1, 0≦y≦1, 0≦z≦1, x+y+z=1) layers on foreign substrates. Addition of other elements in small quantities does not fundamentally alter the process. Two of the above examples included doping the thick films with Si or Mg, while similar doping up to 10% with boron or arsenic can be used to dramatically alter the electronic properties of the nitride film. The composition of the nitride layer may be intentionally or unintentionally inhomogeneous as well. The nitride film may comprise a film structure which could include buffer layers, superlattices, device heterostructures, etc., all having similar or dissimilar compositions to the bulk nitride layer. All such growth profiles are within the scope of this invention.

The film thicknesses described in the preferred embodiment were selected for illustrative purposes only. In practicality, any AlₓIn_{y}Ga_{z}N film in excess of approximately 50μm thick will yield spontaneously separated free-standing wafers in accordance with this invention. The upper limit for film thickness is determined solely by growth system design and will vary from reactor to reactor, but may be considered to be in excess of 20 mm for practical purposes.

The growth process described for the practice of this invention was HVPE. However, alternative deposition techniques may be used provided that they offer a means of annealing the ion implanted layer to facilitate microvoiding and can generate sufficient stress to generate cleavage surfaces following the nitride deposition step.

The wafer separation process indicated that cleavage along a plane parallel to the substrate surface. For some substrates, however, there may be no natural cleavage plane parallel to the substrate surface. However, spontaneous separation may still occur in such substrates, either inhomogeneously or upon prismatic substrate planes. While rougher interfaces may result from this type of separation, they are still compatible with the practice of this invention.

References A substantial body of literature exists pertaining to the use of ion implantation for wafer separation and/or enhanced etch selectivity. Several of these references are set forth below. .

The following references are cited as being relevant to Smart Cut^{™}and are incorporated by reference herein:

1. B. Aspar, et al., Microelectronic Engineering, 36, 233 (1997). This publication provides an overview of the Smart Cut¹⁹⁸ process for forming silicon on insulator wafers.

2. E. Hugonnard-Bruyere, et al., Microelectronic Engineering, 48, 277 (1999). This publication discusses the use of the Smart Cut^{™}technology on 6H-SiC wafers.

3. U.S. Pat. No. 6,794,276 B2, issued Sep. 21, 2004, to Letertre et al., is entitled “Methods for Fabricating a Substrate.” This patent from SOITec Silicon on Insulator Technologies S.A., describes an application of Smart Cut^{™}to nitrides. The process described is essentially conventional Smart Cut^{™}and requires the use of multiple depositions, handle wafers, wafer bonding, and ex situ annealing. It is significantly different from the present invention.

4. U.S. Pat. No. 5,374,564, issued Dec. 20, 1994, to Bruel, is entitled “Process for the Production of Thin Semiconductor Material Films.” This is the original CEA/LETI patent on the technique that would later be trademarked as Smart Cut^{™}.

5. U.S. Pat. No. 6,790,747, issued Sep. 14, 2004, to Henley et al., is entitled “Method and Device for Controlled Cleaving Process.” This is one of approximately 37 patents that Silicon Genesis Corporation has been granted on their version of the Smart Cut¹⁹⁸ process. The vast majority of these patents describe a silicon-on-insulator process, though all of them suggest its applicability to gallium nitride. However, none of these patents cover in situ controlled delamination as has been described in the present invention. For reference, their other patents include U.S. Patent Nos. 6,632,724, 6,582,999, 6,534,381, 6,528,391, 6,514,838, 6,511,899; 6,486,041; 6,458,672; 6,391,740; 6,335,264; 6,321,134; 6,294,814; 6,291,326; 6,291,314; 6,291,313; 6,290,804; 6,287,941; 6,284,631; 6,274,459; 6,248,649; 6,221,774; 6,207,005; 6,187,110; 6,184,111; 6,171,965; 6,162,705; 6,159,825; 6,155,909; 6,153,524; 6,146,979; 6,033,974; 6,013,567; 6,013,563; 6,010,579; 5,994,207; and 5,985,742.

6. U.S. Pat. No. 6,086,673, issued Jul. 11, 2000, to Molnar, is entitled “Process for Producing High-Quality III-V Nitride Substrates.” Dr. Richard Molnar of MIT describes an in situ wafer separation technique similar to that proposed herein. However, there is a very important difference between Molnar's process and the present invention. Molnar specifically requires that a pretreatment layer be applied to the substrate ex situ prior to growth. The present invention eliminates the need for any such pretreatment layer, resulting in reduced processing costs compared to Molnar's approach.

Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of in situ separation of epitaxially-grown nitride films from their foreign substrates, comprising:
selecting a suitable substrate for (Al, In, Ga)N film growth;
implanting foreign ions in the substrate to form a comparatively sharp concentration profile;
growing a (Al, In, Ga)N film on the substrate; and
cooling the film and substrate to introduce thermal expansion mismatch-related strain, wherein the film separates from the substrate spontaneously.

2. The method of claim 1, wherein the substrate is (Al, In, Ga)N, sapphire (Al₂O₃), silicon carbide (SiC), silicon (Si), spinel (MgAl₂O₄), or lithium aluminate (LiA lO₂).

3. The method of claim 1, wherein the foreign ions are hydrogen, helium, argon, or other noble gas ions.

4. The method of claim 1, wherein the implanted foreign ions migrate and coalesce, forming voids in the substrate.

5. The method of claim 4, wherein the voids cause the substrate to spontaneously fracture along a plane parallel to the substrate surface upon cooling.

6. The method of claim 1, wherein the growing step includes heating the substrate.

7. The method of claim 1, wherein the grown film has a thickness of at least 50microns.

8. The method of claim 1, further comprising removing a remaining fragment of the substrate from the grown film by polishing or dry etching.

9. A free standing III:N substrate fabricated using the method of claim 1.

10. An electronic or optoelectronic device co-grown with the film fabricated using the method of claim 1.

11. A method for in situ fabrication of a free-standing wafer, comprising:
(a) providing a substrate having a concentration profile of foreign ions below a surface of the substrate;
(b) depositing a film on the surface of the substrate; and
(c) cooling the substrate and film to introduce thermal expansion mismatch-related strain, wherein the film on top of a membrane that is a fragment of the substrate spontaneously separates from the substrate along the concentration profile, in order to create a free-standing wafer.

12. The method of claim 11, wherein the free-standing wafer minimizes contamination with unwanted impurities.

13. The method of claim 11, wherein the free-standing wafer minimizes pre-growth and post-growth processing.

14. The method of claim 11, wherein the concentration profile is at a specified depth below the substrate surface and the membrane has a thickness given by the specified depth, and the separation is along at least one plane of the substrate.

15. The method of claim 11, wherein the depth is less than 1 micron.

16. The method of claim 11, wherein the step (b) of depositing the film on the surface of the substrate comprises the step of growing the film on the surface of the substrate.

17. The method of claim 11, wherein the free standing wafer is a substrate.

18. The method of claim 11, further comprising removing the fragment of the substrate from the film by polishing or dry etching.

19. The method of claim 11, wherein the free standing wafer minimizes the number of fabrication steps.

20. An electronic or optoelectronic device co-grown with the film fabricated using the method of claim 11.
